(19) United States
(12) Patent Application Publication
(10) Pub. No.: US 2014/0016290 A1
(43) Pub. Date: Jan. 16, 2014

(54) TOUCH PANEL AND METHOD FOR MANUFACTURING THE SAME

(71) Applicants: Seung Min LEE, Gyunggi-do (KR); Tae Hoon KIM, Gyunggi-do (KR); Ho Joon PARK, Gyunggi-do (KR); Wan Jae LEE, Gyunggi-do (KR)

(72) Inventors: Seung Min LEE, Gyunggi-do (KR); Tae Hoon KIM, Gyunggi-do (KR); Ho Joon PARK, Gyunggi-do (KR); Wan Jae LEE, Gyunggi-do (KR)

(73) Assignee: SAMSUNG ELECTRO-MECHANICS CO., LTD., Gyunggi-do (KR)

(21) Appl. No.: 13/615,878

(22) Filed: Sep. 14, 2012

(30) Foreign Application Priority Data
Jul. 16, 2012 (KR) 10-2012-0077344

(51) Int. Cl. H05K 1/14; H05K 3/00

(52) U.S. Cl. 361/792; 29/622

(57) ABSTRACT

Disclosed herein is a touch panel including: a first transparent substrate partitioned into an active area and a bezel area provided in edges of the active area; a mark formed so as to protrude on the bezel area; and a second transparent substrate coupled to the first transparent substrate so that at least one corner thereof corresponds to the mark.

### CROSS REFERENCE TO RELATED APPLICATION

This application claims the benefit of Korean Patent Application No. 10-2012-0077344, filed on Jul. 16, 2012, entitled “Touch Panel and Method for Manufacturing the Same”, which is hereby incorporated by reference in its entirety into this application.

### BACKGROUND OF THE INVENTION

1. Technical Field

The present invention relates to a touch panel and a method for manufacturing the same.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has been widening the use of computers more and more, it is difficult to efficiently operate products using only a keyboard and mouse currently serving as an input device. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of an image display device such as an electronic organizer, a flat panel display device including a liquid crystal display (LCD) device, a plasma display panel (PDP), an electroluminescence (El) element, or the like, and a cathode ray tube (CRT) to thereby be used to allow a user to select desired information while viewing the image display device.

In addition, the touch panel is classified into a resistive type touch panel, a capacitive type touch panel, an electromagnetic type touch panel, a surface acoustic wave (SAW) type touch panel, and an infrared type touch panel. These various types of touch panels are adopted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

Meanwhile, a method for manufacturing a touch panel includes a process of adhering various types of materials to be adhered using an adhesive layer. As such, when the materials to be adhered is adhered using the adhesive layer, a procedure of accurately aligning the materials to be adhered is necessarily required in order to improve reliability of the touch panel. As disclosed in Patent Document 1, a touch panel according to the prior art optically aligns and then adheres the materials to be adhered using an alignment mark and a CCD camera. However, when the material to be adhered is aligned and then is adhered, while being rolled out using a roller or the like, the materials to be adhered may be pushed or inclined to lead to a mis-alignment phenomenon.

### PRIOR ART DOCUMENT

### Patent Document

(Patent Document 1) JP 2008-009054 A

### SUMMARY OF THE INVENTION

The present invention has been made in an effort to provide a touch panel and a method for manufacturing the same capable of preventing a mis-alignment phenomenon of a transparent substrate by physically supporting the transparent substrate using a mark formed so as to protrude on a window when coupling the window and the transparent substrate to each other.

According to a preferred embodiment of the present invention, there is provided a touch panel including: a first transparent substrate partitioned into an active area and a bezel area provided in edges of the active area; a mark formed so as to protrude on the bezel area; and a second transparent substrate coupled to the first transparent substrate so that at least one corner thereof corresponds to the mark.

The touch panel may further include a printed part formed on the bezel area.

The mark may be formed of the same material as that of the printed part.

The mark may have a color different from that of the printed part.

The first transparent substrate may be a window disposed at an outermost side of the touch panel.

The number of marks may be one to four.

The first transparent and the second transparent substrate may be adhered to each other using an adhesive layer so as to be coupled to each other.

The adhesive layer may be an optical clear adhesive (OCA).

The second transparent substrate may be provided with an electrode pattern and an electrode wiring connected to the electrode pattern.

According to another preferred embodiment of the present invention, there is provided a method for manufacturing a touch panel including: preparing a first transparent substrate partitioned into an active area and a bezel area provided in edges of the active area; forming a mark so as to protrude on the bezel area; and coupling a second transparent substrate to the first transparent substrate so that at least one corner thereof corresponds to the mark.

The method may further include, before the forming of the mark, forming a printed part on the bezel area.

The mark may be formed of the same material as that of the printed part.

The mark may have a color different from that of the printed part.

The first transparent substrate may be a window disposed at an outermost side of the touch panel.

In the forming of the mark, the number of marks may be one to four.

In the coupling, the first transparent and the second transparent substrate may be adhered to each other using an adhesive layer so as to be coupled to each other.

The adhesive layer may be an optical clear adhesive (OCA).

The second transparent substrate may be provided with an electrode pattern and an electrode wiring connected to the electrode pattern.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 4 are plan views of a touch panel according to a preferred embodiment of the present invention;

FIG. 5 is a cross-sectional view taken along line A-A′ of the touch panel as shown in FIG. 1;

FIG. 6 is a plan view of a modified example of the touch panel as shown in FIG. 1; and

FIGS. 7 to 10 are plan views sequentially showing the process of a method for manufacturing the touch panel according to the preferred embodiment of the present invention.

### DESCRIPTION OF THE PREFERRED EMBODIMENTS

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

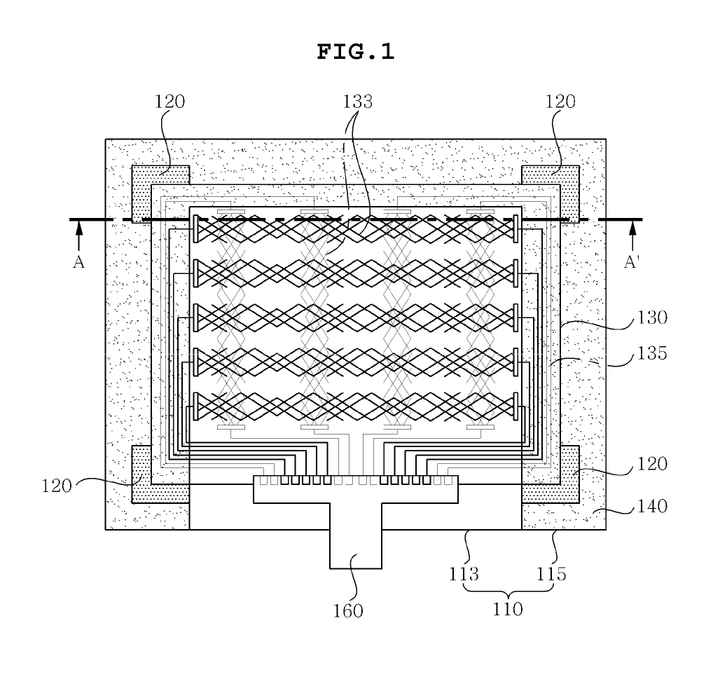

FIGS. 1 to 4 are plan views of a touch panel according to a preferred embodiment of the present invention; and FIG. 5 is a cross-sectional view taken along line A-A′ of the touch panel as shown in FIG. 1.

As shown in FIGS. 1 to 5, the touch panel according to the preferred embodiment of the present invention is configured to include a first transparent substrate 110 partitioned into an active area 113 and a bezel area 115 provided in edges of the active area 113, a mark 120 formed so as to protrude on the bezel area 115, and a second transparent substrate 130 coupled to the first transparent substrate 110 so that at least one corner thereof corresponds to the mark 120.

The first transparent substrate 110 may be a window provided at an outermost side of the touch panel. In the case in which the first transparent substrate 110 is a window, the first transparent substrate 110 may have an exposure surface capable of receiving a touch of a user. Further, the first transparent substrate 110 may be made of a glass, a tempered glass, or the like, but is not necessarily limited thereto. Meanwhile, the first transparent substrate 110 is partitioned into the active area 113 and the bezel area 115. In this configuration, the active area 113 is the area recognizing the touch of user or outputting an image provided from a display. Further, the bezel area 115 is an area provided in edges of the active area 113 and having a printed part 140 formed therein so as to cover electrode wirings 135 or display a logo, or the like. Specifically, the printed part 140 may be printed using a colored ink through a screen printing method or the like, but is not limited thereto.

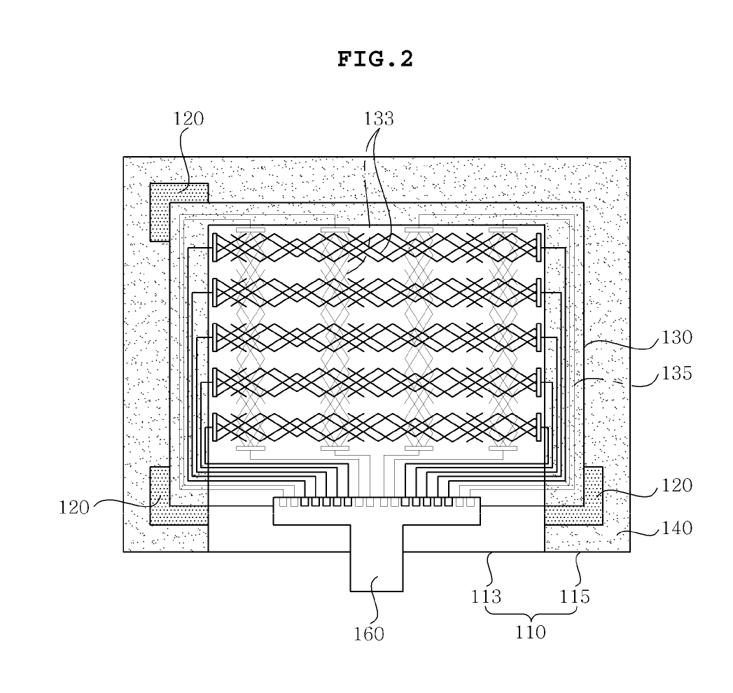

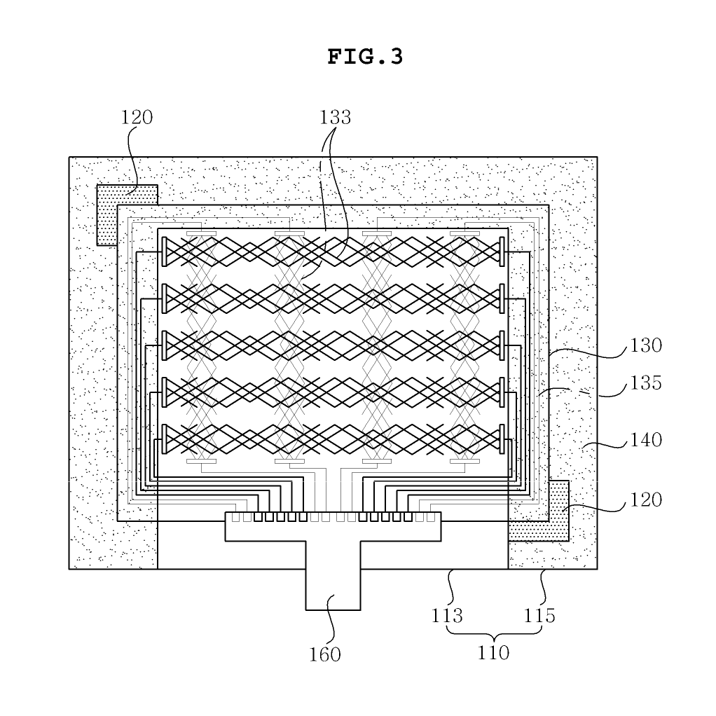

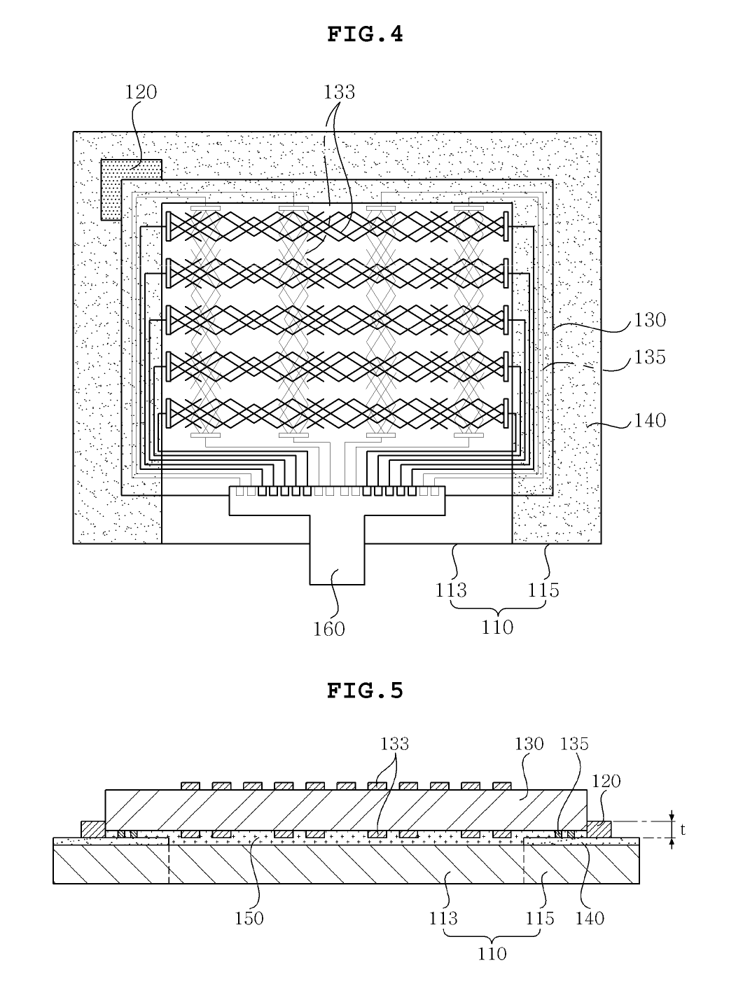

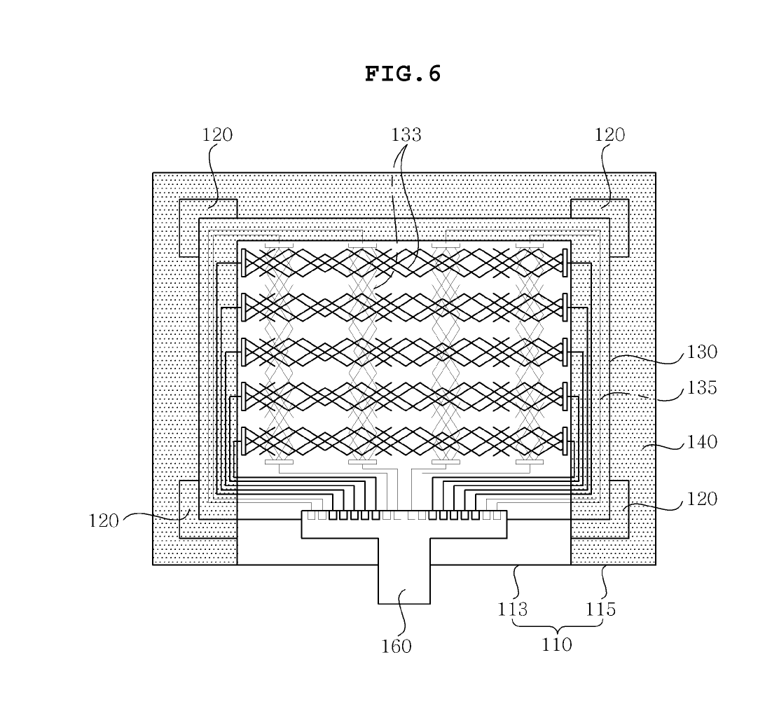

The mark 120 serves to align the second transparent substrate 130 by physically supporting the second transparent substrate 130. Here, the mark 120 is formed so as to protrude on the bezel area 115 of the first transparent substrate 110. That is, the mark 120 may be formed so as to protrude on the bezel area 115 in order to have a predetermined thickness t (see FIG. 5) to thereby physically support a side of the corner of the second transparent substrate 130, thereby making it possible to prevent a mis-alignment phenomenon of the second substrate 130 when coupling the second transparent substrate 130 to the first transparent substrate 110. Specifically, in order to stably support the second transparent substrate 130, four marks 120 may be formed so as to support four corners of the second transparent substrate 130 (see FIG. 1). However, four marks 120 do not need to be formed, and three marks (see FIG. 2), two marks (see FIG. 3) or one mark (see FIG. 4) may be formed, as needed. In addition, although the mark 120 is shown to have a “ [symbol] ”-shape in the drawings, it may also have any modified shapes as long as it may physically support the second transparent substrate 130. Meanwhile, the mark 120 may be formed on the printed part 140, wherein the mark 120 and the printed part 140 may be formed so as to have different colors. For example, as the printed part 140 has a black color and the mark 120 has a red color, a location or a shape of the mark 120 may be clearly recognized visually, and as a result, a coupling state between the first transparent substrate 110 and the second transparent substrate 130 may be easily inspected visually. However, the mark 120 and the printed part 140 do not need to have different colors. FIG. 6 is a plan view of a modified example of the touch panel as shown in FIG. 1, wherein the mark 120 and the printed part 140 may be formed of the same material as shown in FIG. 6. In this case, after the printed part 140 is printed using the colored ink through a screen printing method, or the like, the mark 120 may be printed again using the colored ink through the screen printing method, or the like. As a result, the mark 120 and the printed part 140 may be formed through the same process, whereby a manufacturing process may be simplified.

The transparent substrate 2 serves to provide an area in which electrode patterns 133 and electrode wirings 135 are to be formed. Here, the second transparent substrate 130 needs to have support force supporting the electrode patterns 133 and the electrode wirings 135 and transparency allowing a user to recognize an image provided by a display. In consideration of the support force and the transparency described above, the second transparent substrate 130 may be made of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, tempered glass, or the like, but is not necessarily limited thereto.

Meanwhile, the electrode pattern 133 serves to generate a signal at the time of a touch by a user to allow a controller to recognize a touched coordinate. In addition, the electrode pattern 133 may be formed in a mesh pattern using copper (Cu), aluminum (Al), gold (Au), silver (Ag), titanium (Ti), palladium (Pd), chromium (Cr), or a combination thereof. In addition, the electrode pattern 133 may be formed by a plating process or a depositing process using a sputter. In addition, in the case in which the electrode pattern 133 is made of copper (Cu), a surface of the electrode pattern 133 may be black-oxide treated. As described above, the surface of the electrode pattern 133 is black-oxide treated to prevent light from being reflected, thereby making it possible to improve visibility of the touch panel. Meanwhile, the electrode pattern 133 may also be formed of a metal silver formed by exposing and developing a silver salt emulsion layer, a metal oxide such as indium thin oxide (ITO), or a conductive polymer such as PEDOT/PSS having excellent flexibility and a simple coating process, in addition to the above-mentioned metals. Meanwhile, the electrode pattern 133 is formed to have a bar pattern in the drawings, but is not limited thereto, and the electrode pattern 113 may be formed to have all patterns known in the art, such as a rhombus pattern, a rectangular pattern, a triangular pattern, a circular pattern, and the like.

Meanwhile, the electrode wiring 135 is connected to the electrode pattern 133 to transmit and/or receive electrical signals to and/or from the electrode pattern 133. Here, the electrode wiring 135 is formed integrally with the electrode pattern 130, thereby making it possible to simplify a manufacturing process of the touch panel and to reduce a lead time. Additionally, an end of the electrode wiring 135 may be provided with a flexible printed cable (FPC) 160 in order to connect the electrode wiring 135 to a controller or the like.

Meanwhile, the second transparent substrate 130 on which the electrode pattern 133 and the electrode wiring 135 are formed may be adhered to the first transparent substrate 110 using an adhesive layer 150 (see FIG. 5). Here, an optical clear adhesive (OCA) may be used as the adhesive layer 150. As such, when the second transparent substrate 130 is coupled to the first transparent substrate 110 using the adhesive layer 150, at least one corner of the second transparent substrate 130 may be disposed so as to correspond to the mark 120. Therefore, the second transparent substrate 130 is physically supported by the mark 120 formed so as to protrude on the bezel area 115. Therefore, when the second transparent substrate 130 is coupled to the first transparent substrate 110, a mis-alignment phenomenon of the second substrate 130 may be prevented and the second transparent substrate 130 may be coupled to the first transparent substrate 110 within a fixed range of error. In addition, even when the second transparent substrate 130 is adhered to the first transparent substrate 110, while being rolled-out using a roller, the second transparent substrate 130 is supported by the mark 120, thereby preventing a phenomenon that the second transparent substrate 130 is pushed or inclined.

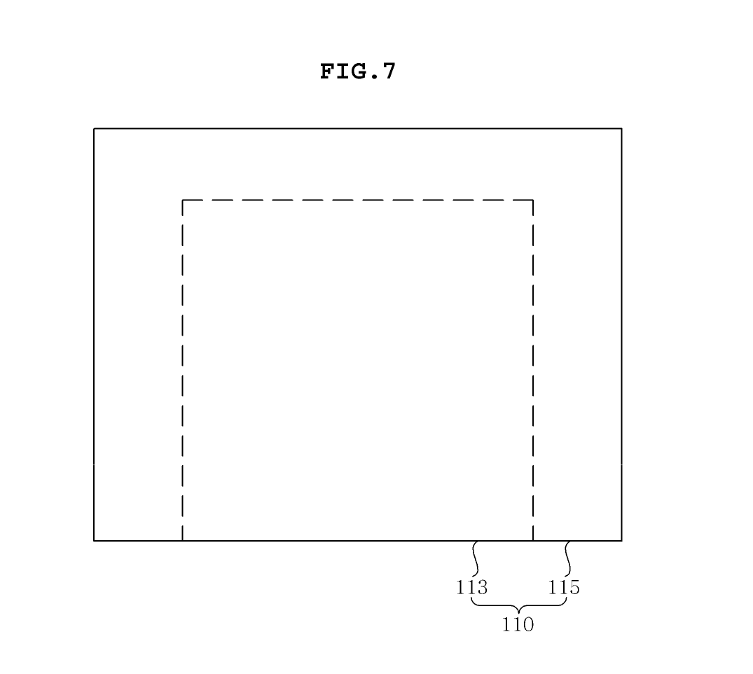

FIGS. 7 to 10 are plan views sequentially showing the process of a method for manufacturing the touch panel according to the preferred embodiment of the present invention.

As shown in FIGS. 7 to 10, the method for manufacturing the touch panel according to the preferred embodiment of the present invention is configured to include (A) preparing a first transparent substrate 110 partitioned into an active region 113 and a bezel region 115 provided in edges of the active region 113, (B) forming a mark 120 so as to protrude on the bezel region 115, and (C) coupling a second transparent substrate 130 to the first transparent substrate 110 so that at least one corner of the second transparent substrate 130 corresponds to the mark 120.

First, as shown in FIG. 7, the first transparent substrate 110 is prepared. Here, the first transparent substrate 110 is partitioned into the active area 113 and the bezel area 115 provided in edges of the active area 113. In this configuration, the active area 113 is an area in which a touch of a user is recognized or an image provided by the display is output, and the bezel area 115 is an area in which an electrode wiring 135 is covered or a logo or the like is displayed. Meanwhile, the first transparent substrate 110 may be a window provided at an outermost side of the touch panel to thereby receive the touch of the user.

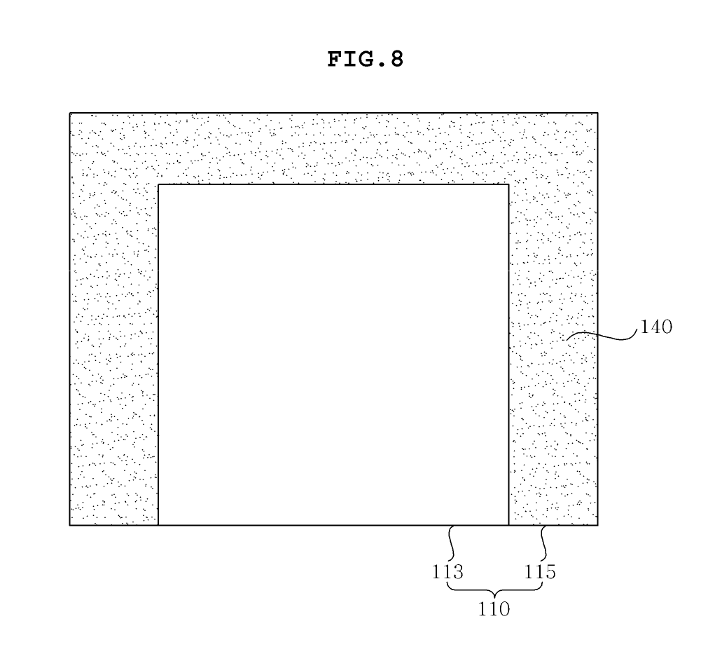

Next, as shown in FIG. 8, a printed part 140 is formed on the bezel area 115 of the first transparent substrate 110. Here, a method of forming the printed part 140 is not specifically limited, but the printed part 140 may be printed using a colored ink through a screen printing method or the like.

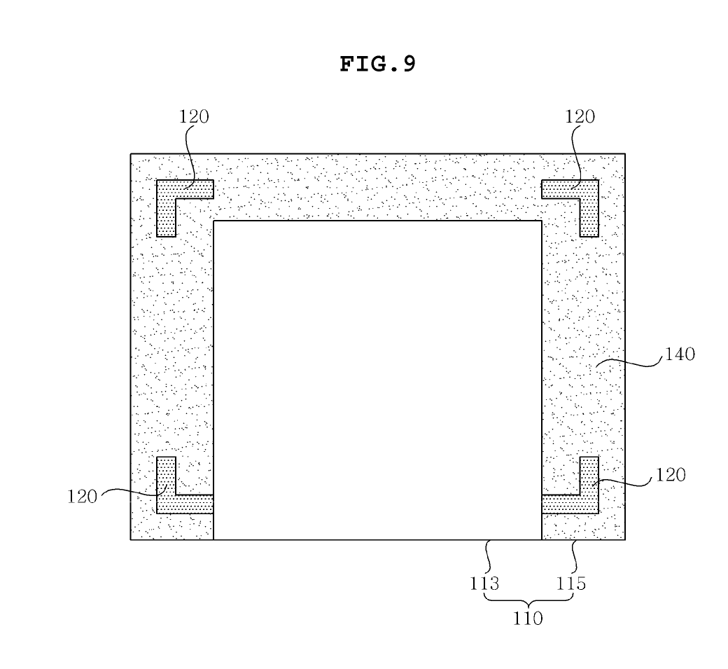

Next, as shown in FIG. 9, the mark 120 is formed. Here, the mark 120 is formed so as to protrude on the bezel area 115. Here, the mark 120 serves to physically support and align the second transparent substrate 130 in a subsequent operation. In addition, the mark 120 may be formed on the printed part 140, wherein the mark 120 and the printed part 140 may be formed so as to have different colors in order to clearly recognize visually a location or a shape of the mark 120. However, the mark 120 and the printed part 140 do not need to have different colors and may be formed of the same material (see FIG. 6). In addition, four marks 120 may be formed in order to stably support the second transparent substrate 130, but this is an illustrative example, and three marks (see FIG. 2), two marks (see FIG. 3) or one mark (see FIG. 4) may be formed. Meanwhile, a method of forming the mark 120 is not specifically limited, but the mark 120 may be printed through a screen printing or the like, similar to the printed part 140.

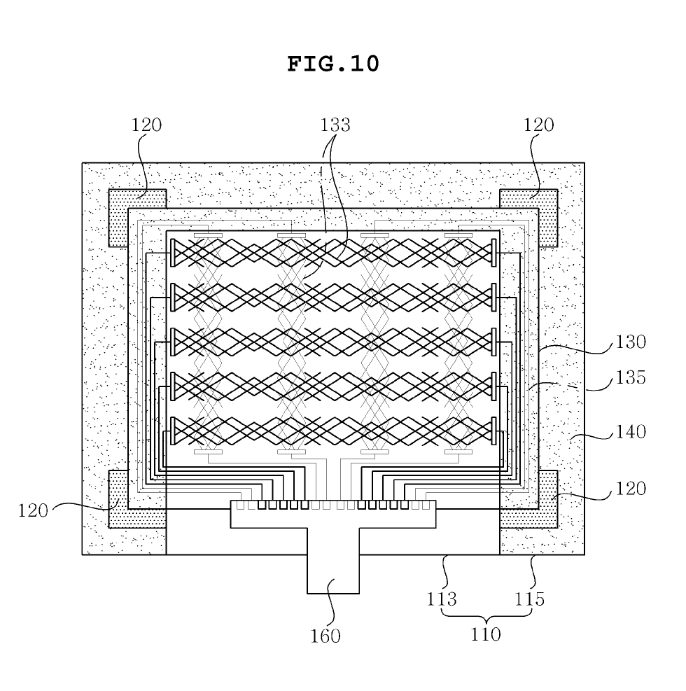

Next, as shown in FIG. 10, the second transparent substrate 130 is coupled to the first transparent substrate 110. Here, the second transparent substrate 130 may be provided with an electrode pattern 133 generating a signal at the time of a touch by a user to allow a controller to recognize a touched coordinate and an electrode wiring 135 transmitting and/or receiving electrical signals to and/or from the electrode pattern 133. In addition, an end of the electrode wiring 135 may be provided with a flexible printed cable (FPC) 160 connected to the controller or the like. Meanwhile, the second transparent substrate 130 may be coupled to the first transparent substrate 110 so that at least one corner of the second transparent substrate 130 corresponds to the mark 120. Here, the mark 120 formed so as to protrude on the bezel area 115 physically supports the corner of the second transparent substrate 130. Therefore, a mis-alignment phenomenon of the second substrate 130 may be prevented and the second transparent substrate 130 may be coupled to the first transparent substrate 110 within a fixed range of error. In addition, even when the second transparent substrate 130 is aligned and is then adhered to the first transparent substrate 110, while being rolled-out using a roller, the second transparent substrate 130 is supported by the mark 120, thereby preventing a phenomenon that the second transparent substrate 130 is pushed or inclined. Meanwhile, the second transparent substrate 130 may be adhered to the first transparent substrate 110 using an adhesive layer 150, such as an optical clear adhesive (OCA) (see FIG. 5).

As set forth above, according to the preferred embodiment of the present invention, a mis-alignment phenomenon of a transparent substrate may be prevented by physically supporting the transparent substrate using a mark formed so as to protrude on a window when coupling the window and the transparent substrate to each other. Therefore, replacement costs of a window or a transparent substrate that may occur due to the mis-alignment phenomenon of the transparent substrate can be reduced.

In addition, according to the preferred embodiment of the present invention, the transparent substrate is physically supported to be accurately aligned by the mark protruding on the window, such that a phenomenon that the transparent substrate is pushed or inclined even when the transparent substrate is adhered to the window, while being rolled-out using the roller, thereby making it possible to improve reliability of the touch panel.

In addition, according to the preferred embodiment of the present invention, the transparent substrate is physically supported to be accurately aligned by the mark protruding on the window, such that the transparent substrate can be coupled to the window in the fixed range of error.

In addition, according to the preferred embodiment of the present invention, the mark has a color different from that of the printed part of the window, such that the coupling state between the window and the transparent substrate can be easily inspected visually.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel comprising:
a first transparent substrate partitioned into an active area and a bezel area provided in edges of the active area;
a mark formed so as to protrude on the bezel area; and
a second transparent substrate coupled to the first transparent substrate so that at least one corner thereof corresponds to the mark.

2. The touch panel as set forth in claim 1, further comprising a printed part formed on the bezel area.

3. The touch panel as set forth in claim 2, wherein the mark is formed of the same material as that of the printed part.

4. The touch panel as set forth in claim 2, wherein the mark has a color different from that of the printed part.

5. The touch panel as set forth in claim 1, wherein the first transparent substrate is a window disposed at an outermost side of the touch panel.

6. The touch panel as set forth in claim 1, wherein the number of marks is one to four.

7. Touch panel as set forth in claim 1, wherein the first transparent and the second transparent substrate are adhered to each other using an adhesive layer so as to be coupled to each other.

8. The touch panel as set forth in claim 7, wherein the adhesive layer is an optical clear adhesive (OCA).

9. The touch panel as set forth in claim 1, wherein the second transparent substrate is provided with an electrode pattern and an electrode wiring connected to the electrode pattern.

10. A method for manufacturing a touch panel, the method comprising:
preparing a first transparent substrate partitioned into an active area and a bezel area provided in edges of the active area;
forming a mark so as to protrude on the bezel area; and
coupling a second transparent substrate to the first transparent substrate so that at least one corner thereof corresponds to the mark.

11. The method as set forth in claim 10, further comprising, before the forming of the mark, forming a printed part on the bezel area.

12. The method as set forth in claim 11, wherein the mark is formed of the same material as that of the printed part.

13. The method as set forth in claim 11, wherein the mark has a color different from that of the printed part.

14. The method as set forth in claim 10, wherein the first transparent substrate is a window disposed at an outermost side of the touch panel.

15. The method as set forth in claim 10, wherein in the forming of the mark, the number of marks is one to four.

16. The method as set forth in claim 10, wherein in the coupling, the first transparent and the second transparent substrate are adhered to each other using an adhesive layer so as to be coupled to each other.

17. The method as set forth in claim 16, wherein the adhesive layer is an optical clear adhesive (OCA).

18. The method as set forth in claim 10, wherein the second transparent substrate is provided with an electrode pattern and an electrode wiring connected to the electrode pattern.
